(19) United States
(12) Patent Application Publication
(10) Pub. No.: US 2020/0116900 A1
(43) Pub. Date: Apr. 16, 2020

(54) METALENS, METHOD FOR MAKING SAME, AND OPTICAL DEVICE USING SAME

(71) Applicants: Interface Technology (ChengDu) Co., Ltd., Chengdu (CN); INTERFACE OPTOELECTRONICS (SHENZHEN) CO., LTD., Shenzhen (CN); GENERAL INTERFACE SOLUTION LIMITED, Zhunan (TW)

(72) Inventors: CHI-FENG CHIU, Zhunan (TW); MING-HUNG TSAI, Zhunan (TW)

(21) Appl. No.: 16/236,548

(22) Filed: Dec. 30, 2018

(30) Foreign Application Priority Data
Oct. 11, 2018 (CN) 201811183599.1

(51) Int. Cl. G02B 3/00; G02B 5/02; G03F 7/00

(52) U.S. Cl. CPC G02B 3/00; G02B 2003/0093; G03F 7/0005; G02B 5/0278

(57) ABSTRACT

A metalens of greatly reduced depth includes a lens body and many columnar microstructures. The lens body includes first and second surfaces. The columnar microstructures are formed on the first surface and spaced apart from each other. Each columnar microstructure has a particular shape and extends in a direction away from the first surface to a height of 500 nm to 1500 nm. The present disclosure also provides a method for making the above metalens and an optical element using the metalens.

### FIELD

The subject matter herein generally relates to a metalens, a method for making the metalens, and an optical device using the metalens.

### BACKGROUND

An optical device for face recognition and having a 3D depth detecting function includes a laser light source, a collimating lens, and a diffractive lens stacked in that order. The laser light emitted by the laser light source regularly arranged is converted into parallel beams by passing through the collimating lens, then the parallel beams pass through the diffractive lens to form a divergent light beam having a divergence angle of 60 degrees to 70 degrees, which is emitted onto a target object. However, the diffractive lens has a fine irregular diffractive microstructure and requires high precision in processing. In addition, the optical device also requires the collimating lens and the diffractive lens being aligned precisely during assembly.

Therefore, there is room for improvement in the art.

### BRIEF DESCRIPTION OF THE DRAWINGS

Implementations of the present technology will now be described, by way of embodiments, with reference to the attached figures.

FIG. 1 is a planar view of a metalens according to an embodiment of the present disclosure.

FIG. 2 is a cross-sectional view along line II-II of FIG. 1.

FIG. 3A through FIG. 3F are schematic views showing a method for making a metalens according to an embodiment of the present disclosure.

FIG. 4 is a flowchart for making a metalens according to an embodiment of the present disclosure.

FIG. 5 is a cross-sectional view of an optical device using the metalens of FIG. 1.

### DETAILED DESCRIPTION

It will be appreciated that for simplicity and clarity of illustration, where appropriate, reference numerals have been repeated among the different figures to indicate corresponding or analogous elements. In addition, numerous specific details are set forth in order to provide a thorough understanding of the embodiments described herein. However, it will be understood by those of ordinary skill in the art that the embodiments described herein may be practiced without these specific details. In other instances, methods, procedures, and components have not been described in detail so as not to obscure the related relevant feature being described. Also, the description is not to be considered as limiting the scope of the embodiments described herein. The drawings are not necessarily to scale and the proportions of certain parts may be exaggerated to better illustrate details and features of the present disclosure.

The term “coupled” is defined as connected, whether directly or indirectly through intervening components, and is not necessarily limited to physical connections. The connection can be such that the objects are permanently connected or releasably connected. The term “comprising” when utilized, means “including, but not necessarily limited to”; it specifically indicates open-ended inclusion or membership in the so-described combination, group, series, and the like.

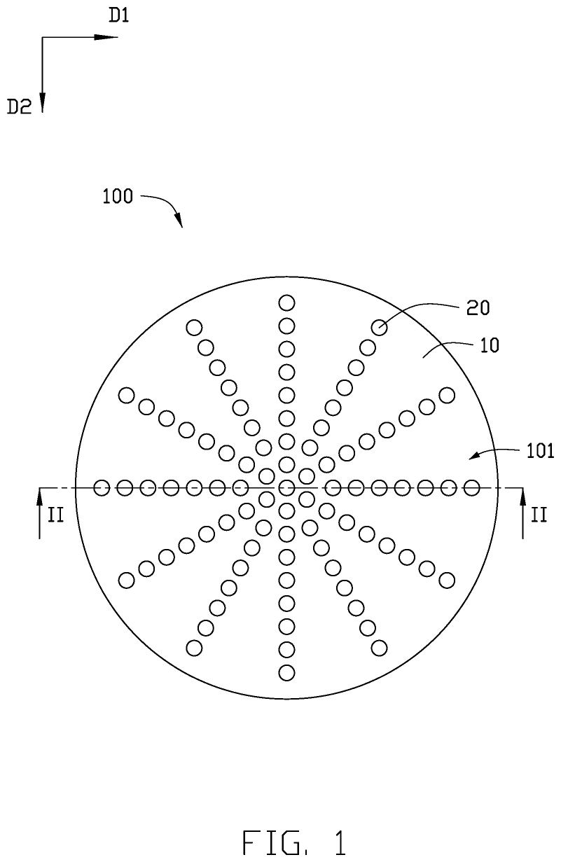

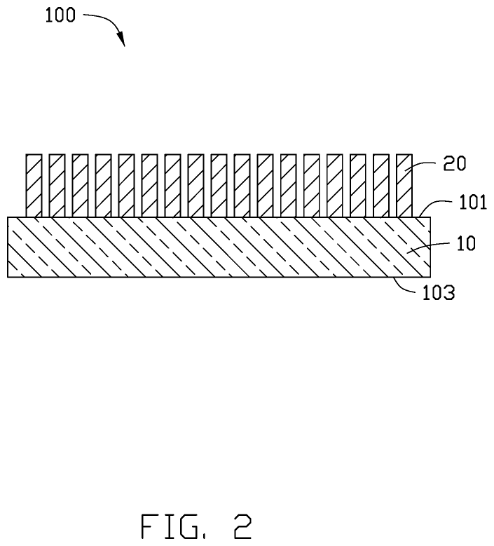

As shown in FIG. 1 and FIG. 2, metalens 100 according to an embodiment of the present disclosure comprises a lens body 10 and a plurality of columnar microstructures 20 formed on the lens body 10. As shown in FIG. 2, the lens body comprises a first surface 101 and a second surface 103 opposite the first surface 101, the columnar microstructures are formed on the first surface 101 and spaced apart from each other. In an embodiment, each columnar microstructure 20 is substantially perpendicular to the first surface 101. Each columnar microstructure 20 has a cylindrical shape and extends in a direction perpendicular to the first surface 101 of the lens body 10 to a height of 500 nm to 1500 nm. In other embodiments, the columnar microstructures 20 may have prismatic shapes.

As shown in FIG. 1, in an embodiment, each columnar microstructure 20 has a length of 20 nm to 200 nm along a first direction D1, and has a width of 20 nm to 200 nm along a second direction D2. The first direction D1 is orthogonal to the second direction D2, and the first direction D1 and the second direction D2 are both parallel to the first surface 101 of the lens body 10. The length and width of the columnar microstructure 20 are such as to affect wavefronts of different wavelengths (wavefront is a curved surface formed by the equipotential surface at which the wave propagates to a position). The columnar microstructures 20 may be arranged in a particular pattern such as an L-shape, a T-shape, or an I-shape. The columnar microstructures 20 in the particular pattern may be arranged evenly.

The lens body 10 may be made of a light transmissive material such as glass or sapphire. A material of the columnar microstructure 20 may be the same as or different from the material of the lens body 10, for example, the columnar microstructures 20 may be made of one of other transparent materials different from the material of the lens body 10. In an embodiment, the columnar microstructures 20 may be made of non-transparent materials, such as metal or semiconductor materials, the semiconductor materials may comprise gallium nitride, but are not limited thereto.

A side of the metalens 100 provided with the columnar microstructures 20 is a light exiting side, and the second surface 103 of the lens body 10 is a light incident surface of the metalens 100. When using the metalens 100, light is incident on the lens body 10 beginning with the second surface 103, passes through the lens body 10 and the columnar microstructures 20, and is emitted. Light is directly emitted from the position of the lens body 10 where the columnar microstructures 20 are not provided. The metalens 100 can receive the light falling on a surface and convert the light into a predetermined pattern.

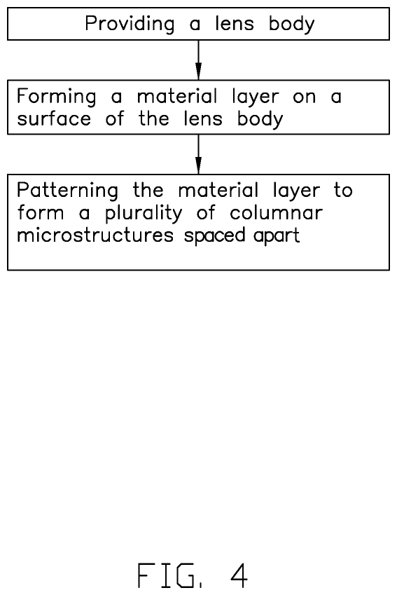

As shown in FIG. 4, a method for making a metalens 100 according to an embodiment of the present disclosure comprises:

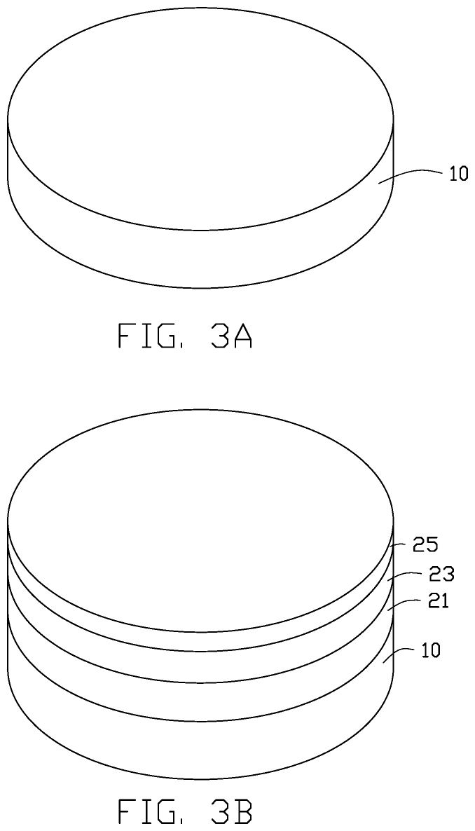

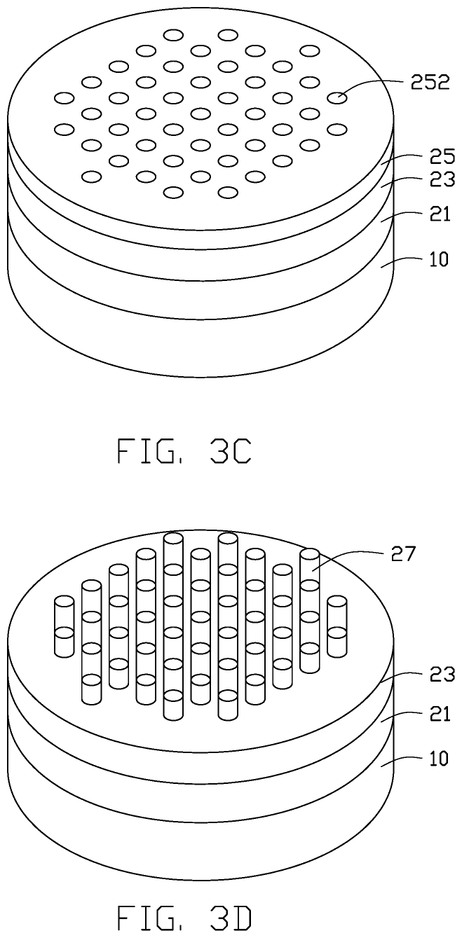

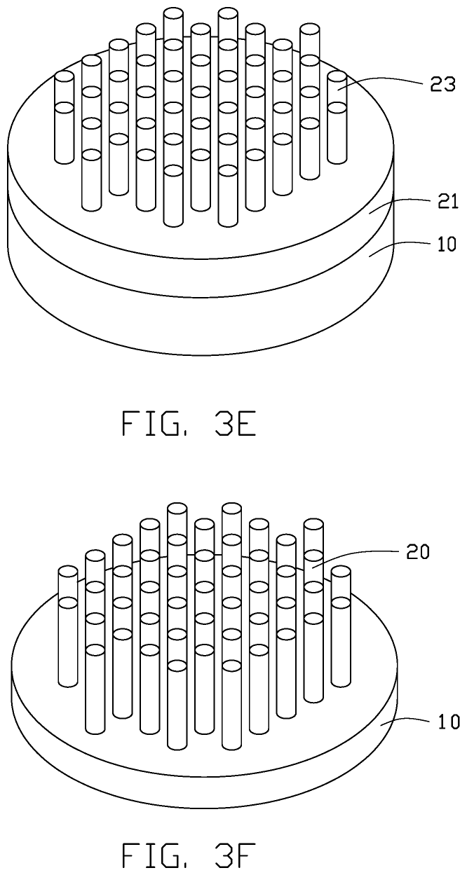

Step S1: a lens body 10 is provided, as shown in FIG. 3A;

Step S2: a material layer 21 is formed on a surface of the lens body 10, as shown in FIG. 3B;

Step S3: the material layer 21 is patterned to form columnar microstructures 20 spaced apart from each other, as shown in FIGS. 3B to 3F;

In an embodiment, the lens body 10 in step S1 is a double-sided polished sapphire.

In an embodiment, the material layer 21 is a continuous gallium nitride layer, not limited to gallium nitride, may be other materials such as a transparent material, a metal material, or other semiconductor materials.

In an embodiment, the gallium nitride layer in step S2 is formed by metal organic compound chemical vapor deposition, for example, trimethylgallium (TMGa) can be used as a gallium source, ammonia gas is used as a nitrogen source, and high-purity hydrogen gas is used as a carrier gas. Thickness of the gallium nitride layer formed is about 800 nm. The surface of the lens body 10 (sapphire) can be cleaned before the material layer 21 is formed, for example, impurities and oxides on the surface of the lens body 10 may be removed by high-temperature heat treatment in a hydrogen gas atmosphere.

In an embodiment, step S3 further comprises forming a hard masking layer 23 and a photoresist layer 25 on the material layer 21, as shown in FIG. 3B. In an embodiment, the hard masking layer 23 is a silicon dioxide layer formed by metal organic chemical vapor deposition and having a thickness of about 400 nm. In an embodiment, the photoresist layer 25 is formed by a coating method such as spin coating, and has a thickness of about 100 nm.

Step S3 further comprises patterning the photoresist layer 25 (for example, using an exposure and development technique) to make the photoresist layer 25 form columnar micropores 252 spaced apart from each other, as shown in FIG. 3C. A chromium layer is then deposited on the patterned photoresist layer 25 (for example, by using an electron gun evaporator device) and upon removing the photoresist layer attached to the hard masking layer (silicon dioxide), columnar microstructured chromium layers 27, spaced apart from each other, remain. In the embodiment, the chromium layers 27 of the columnar microstructures may include circular shapes, rectangular, or any other shape of columnar structure, as shown in FIG. 3D. The chromium layer 27 is used as an etching mask, and the hard masking layer 23 is etched (for example, by reactive ion etching), and the hard masking layer 23 is patterned onto microstructured hard masking layer, the microstructures being spaced apart from each other, as shown in FIG. 3E. The hard masking layer 23 is used as a mask, and the material layer 21 is etched (for example, by inductively coupled plasma reactive ion etching), to pattern the material layer 21 into columnar microstructures 20 spaced apart from each other. The remaining hard masking layer is removed, as shown in FIG. 3F. However, step S3 is not limited to the above method, other methods also may be used, for example, a mask can be employed to pattern the material layer 21 and form columnar microstructures 20 spaced apart from each other.

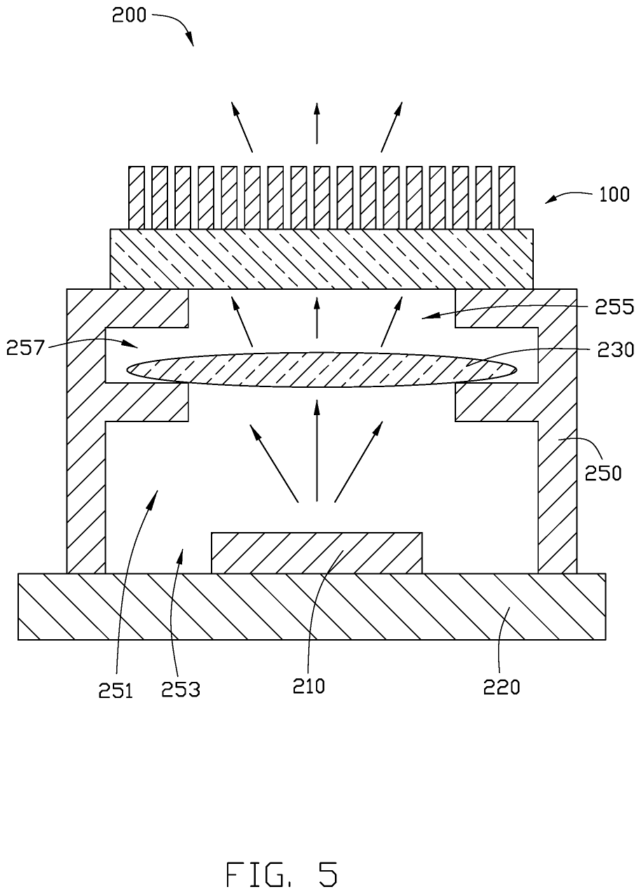

As shown in FIG. 5, an optical device 200 using the above-mentioned metalens 100 comprises a light source 210, an optical diffusing element 230, and a metalens 100 stacked in that order from bottom to top. The optical diffusing element 230 is located between the light source 210 and the metalens 100 and is spaced apart from the light source 210 and the metalens 100. The light source 210 emits light, and the optical diffusing element 230 and the metalens 100 are located on a light transmission path from the light source.

The light source 210 is fixed on a substrate 220, the substrate 220 may be a printed circuit board (PCB). The light source 210 can be a self-illuminating light source, such as a laser light source, an LED, a light bulb, an active matrix organic light emitting diode (AMOLED), or an LCD projection.

The optical diffusing element 230 converts the light pattern into a surface light source, but if the light pattern of the light source 210 is itself a surface light source such as an AMOLED/LCD, the optical diffusing element 230 can be omitted.

The light source 210 of the optical device 200 is not limited to being a collimated laser source, a conventional point source or surface source can also be used as a light source. The metalens 100 can receive the light of the light source and convert the light source beams into a predetermined pattern.

When using the optical device 200, incident light emitted from the light source 210 onto the optical diffusing element 230 is converted into divergent light, the diverged light is then converted into a predetermined pattern by the metalens 100.

In order to secure the light source 210, the optical diffusing element 230, and the metalens 100, the optical device 200 further comprises a support 250 for fixing and aligning the optical diffusing element 230 and the metalens 100. The support 250 is formed in an accommodating space 251, the accommodating space 251 has a first opening 253 and a second opening 255 opposite to the first opening 253. The light source 210 is located at the first opening 253, and the substrate 220 of the light source 210 may enclose the first opening 253. The metalens 100 is located at the second opening 255 to enclose the second opening 255. The optical diffusing element 230 is located in the accommodating space 251 between the first opening 253 and the second opening 255.

In order to fix the optical diffusing element 230 in the accommodating space 251, the surface of the support 250 facing the accommodating space 251 is provided with at least one holding groove 257. The holding groove 257 is used for holding a edge portion of the optical diffusing element 230 into the holding groove 257, such that the optical diffusing element 230 is fixed to the support 250. In addition, in order to fix the optical diffusing element 230 and the metalens 100 on the support 250, an adhesive layer may be provided in a region where the optical diffusing element 230 is in contact with the support 250, and an adhesive layer may be provided in a region where the metalens 100 is in contact with the support 250.

It is to be understood, even though information and advantages of the present embodiments have been set forth in the foregoing description, together with details of the structures and functions of the present embodiments, the disclosure is illustrative only; changes may be made in detail, especially in matters of shape, size, and arrangement of parts within the principles of the present embodiments to the full extent indicated by the plain meaning of the terms in which the appended claims are expressed.

What is claimed is:

1. A metalens, comprising:
a lens body, wherein the lens body comprising a first surface and a second surface opposite to each other;
a plurality of columnar microstructures; wherein the plurality of columnar microstructures are formed on the first surface and spaced apart from each other;
wherein each of the plurality of columnar microstructures has a columnar shape and extends in a direction away from the first surface to a height of 500 nm to 1500 nm.

2. The metalens of claim 1, wherein each of the plurality of columnar microstructure has a length of 20 nm to 200 nm along a first direction, each of the plurality of columnar microstructure has a width of 20 nm to 200 nm along a second direction;
the first direction is orthogonal to the second direction; and
the first direction and the second direction are both parallel to the first surface.

3. The metalens of claim 1, wherein the plurality of columnar microstructures are arranged evenly in a pattern.

4. The metalens of claim 3, wherein the plurality of columnar microstructures are arranged in one of an L-shape, a T-shape or an I-shape.

5. The metalens of claim 1, wherein the second surface of the lens body is a light incident surface;
a side of the metalens provided with the plurality of columnar microstructures is a light exiting side.

6. A optical device, comprising:
light source adapted to emitting light
metalens, wherein the metalens is spaced apart from the light source and located on a path which the light emitted from the light source passes through;
a plurality of columnar microstructures, wherein the plurality of columnar microstructures are formed on the first surface and spaced apart from each other;
wherein each of the plurality of columnar microstructures has a columnar shape and extends in a direction away from the first surface by a height of 500 nm to 1500 nm.

7. The optical device of claim 6, wherein each of the plurality of columnar microstructure has a length of 20 nm to 200 nm along a first direction, each of the plurality of columnar microstructure has a width of 20 nm to 200 nm along a second direction;
the first direction is orthogonal to the second direction; and
the first direction and the second direction are both parallel to the first surface.

8. The optical device of claim 6, wherein the plurality of columnar microstructures are arranged evenly in a pattern.

9. The optical device of claim 6, wherein the second surface of the lens body is a light incident surface;
a side of the metalens provided with the plurality of columnar microstructures is a light exiting side.

10. The optical device of claim 6, wherein the optical device further comprises an optical diffusing element located between the light source and the metalens, the optical diffusing element is adapted for converting a light pattern of light from a light source into a surface light source, the optical diffusing element is spaced apart from the light source and the metalens.

11. The optical device of claim 10, wherein the optical device further comprises a support, the support is formed with an accommodating space, the accommodating space has a first opening and a second opening opposite to the first opening,
the light source is located at the first opening, the metalens is located at the second opening to enclose the second opening; and
the optical diffusing element is located in the accommodating space between the first opening and the second opening.

12. The optical device of claim 11, wherein a surface of the support facing the accommodating space is provided with at least one holding groove, the at least one holding groove is configured for holding an edge portion of the optical diffusing element into the holding groove to fix the optical diffusing element to the support.

13. A method for making a metalens, comprises:
providing a lens body, where the lens body comprising a first surface and a second surface opposite to each other;
forming a material layer on the first surface of the lens body; and
patterning the material layer to form a plurality of columnar microstructures spaced apart from each other;
wherein each of the plurality of columnar microstructures has a columnar shape and extends in a direction away from the first surface to a height of 500 nm to 1500 nm.

14. The method of claim 13, wherein after the mateiral layer is formed and before the plurality of columnar microstructures are formed, the method for making a metalens further comprises:
forming a hard masking layer and a photoresist layer on the material layer sequentially;
patterning the photoresist layer to form a plurality of columnar micropores spaced apart from each other;
depositing a chromium layer on the photoresist layer;
removing the photoresist layer, leaving a plurality of columnar microstructured chromium layers spaced apart from each other;
etching the hard masking layer by using the plurality of columnar microstructured chromium layer as an etching mask to form a plurality of microstructured hard masking layer;
etching the material layer by using the plurality of microstructured hard masking layer as an etching mask to formed a plurality of columnar microstructures spaced apart from each other;
removing the plurality of microstructured hard masking layer.
